(19) United States
(12) Patent Application Publication
(10) Pub. No.: US 2022/0258626 A1
(43) Pub. Date: Aug. 18, 2022

(54) Method and means for electric vehicle battery charging

(71) Applicant: Mikko Kalervo VAANANEN, Helsinki (FI)

(72) Inventor: Mikko Kalervo VAANANEN, Helsinki (FI)

(21) Appl. No.: 17/670,545

(22) Filed: Feb. 14, 2022

Related U.S. Application Data
(60) Provisional application No. 63/150,139, filed on Feb. 17, 2021.

(51) Int. Cl. B60L 53/14; H01B 12/12; H01B 12/04; H01M 50/522; B60L 50/60

(52) U.S. Cl. CPC B60L 53/14; H01B 12/12; H01B 12/16; H01M 50/522; B60L 50/60; H01B 12/04

(57) ABSTRACT

The invention relates to power systems. More particularly, the invention relates to electric vehicle battery charging systems. In the invention a superconducting conductor is used to charge the electric car battery, resulting in a short charging time.

### TECHNICAL FIELD OF INVENTION

The invention relates to power systems. More particularly, the invention relates to electric vehicle battery charging systems.

### BACKGROUND

It is game over for the internal combustion engine in the free markets. The electric vehicle can be designed in more consumer friendly and environmentally friendly fashion to result in a superior end product.

Why then, are people still buying ICE (Internal Combustion Engine) vehicles? The answer is simple. The ICE is easier to refuel than the electric vehicle is to recharge.

The global adoption of the electric vehicle is primarily inhibited by the above disadvantage that the electric vehicle has.

This invention will now remove this disadvantage.

### SUMMARY

The invention under study is directed towards a system and a method for effectively charging an electric vehicle in a few seconds. This is achieved by harnessing superconductivity for the time period within which the electric battery charger charges the battery of the electric vehicle with electricity. This allows the deposition of a very large electric charge into the battery of the electric vehicle in a very short time, without causing the electric vehicle or the battery to overheat or burn.

A further object of the invention is to present superconducting electrical conductors that are used to achieve the inventive system.

One aspect of the invention involves an electrical conductor with a critical temperature that is as high as possible. This conductor is insulated with an inert coolant liquid such as liquid Nitrogen N₂ or CF₄. The cooled, insulated superconducting electrical conductor is used to deposit a large and/or full electric charge without electric resistance to the battery of the electric vehicle.

An electric vehicle in accordance with the invention comprises a rechargeable battery, and an electrical conductor via which the rechargeable battery is configured to be charged with electricity and is characterized in that,
the electrical conductor is surrounded or in contact with a coolant, cooling the electrical conductor below the characteristic T_{c} (critical temperature) of the electrical conductor material,
the electrical conductor is superconducting.

An electric vehicle battery charger in accordance with the invention is configured to charge a rechargeable battery, and comprises an electrical conductor via which the rechargeable battery is configured to be charged with electricity and is characterized in that,
the electrical conductor is surrounded or in contact with a coolant, cooling the electrical conductor below the characteristic T_{c} (critical temperature) of the electrical conductor material,
the electrical conductor is superconducting.

An electric vehicle charging software program product in accordance with the invention is stored in a non-transitory memory medium, configured to operate a system comprising a rechargeable battery, and an electrical conductor via which the rechargeable battery is configured to be charged with electricity and characterized in that,
the electrical conductor is surrounded or in contact with a coolant, cooling the electrical conductor below the characteristic T_{c} (critical temperature) of the electrical conductor material,
the electrical conductor is superconducting,
the software is configured to measure either with sensors or with use data the amount of electric charge lacking from the electric vehicle battery, and
the software is configured to instruct an electric charger to deposit a determined electric charge through the superconducting electric conductor.

In addition, and with reference to the aforementioned advantage accruing embodiments, the best mode of the invention is considered to be using CF₄ or liquid nitrogen as the coolant. In the best mode the electrical conductor is made of Hydrogen Sulfide H₂S. The H₂S electrical conductor is highly pressurised, then preferably after pressurization cooled, and kept pressurised to form an electrical conduit with T_{c}=203 K or so at 200 GPa (GigaPascal). Some sulphur might optionally also be replaced with phosphorus to elevate T_{c} with higher pressures than 200 GPa possibly to above 273 K. These materials exhibit superconductivity at temperatures at which CF₄ and liquid nitrogen, and possibly other known coolants, stably remain as liquids. In the best mode, both the electrical conductors of the battery charger and the electrical conductor in the vehicle leading to the battery will be kept below critical temperature.

This way a large amount of electric charge can be deposited from the charger to the battery of the vehicle without causing overheating in the battery, vehicle or the charger. Optionally all or some parts of the battery are cooled below the critical temperature T_{c} of the battery. In the best mode, a software program can be used to read out a measurement from the battery, determine the amount of charge it can accept at that time, and deposit just the right amount of charge into the battery.

### BRIEF DESCRIPTION OF THE DRAWINGS

In the following the invention will be described in greater detail with reference to exemplary embodiments in accordance with the accompanying drawings, in which

FIG. 1 demonstrates the discovery of superconducting materials from 1900 to 2015 X-axis, and the Critical Temperature in Kelvins at which superconductivity occurs for a particular material.

FIG. 2 demonstrates an embodiment 20 of an electric vehicle in accordance with the invention.

FIG. 3 demonstrates an embodiment 30 of an electric vehicle battery charger in accordance with the invention.

Some of the embodiments are described in the dependent claims.

### DETAILED DESCRIPTION OF EMBODIMENTS

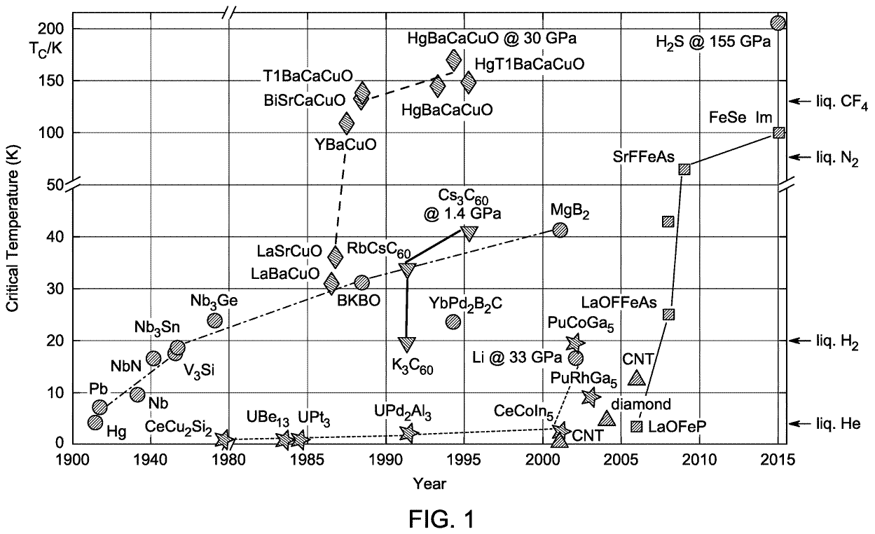

FIG. 1. shows a number of superconducting materials. On the vertical Y-axis on the left, is the T_{c} the critical temperature of the superconducting material, i.e. the temperature below which the material is superconducting. On the horizontal X-axis is the year of discovery. On the vertical axis on the right, are the temperatures where typical coolants still are liquids. The invention works best typically at a temperature as high as possible as a higher temperature is easier to obtain, so therefore liquid nitrogen and CH₄ would probably be the best coolants. This would limit the choice of the conductors to HgTlBaCaCuO, HgBaCaCuO at high pressure similar to 30 GPa, HgBaCaCuO, TlBaCaCuO, BiSrCaCuO, YBaCuO, SrFFeAs, FeSe Im and/or H₂S at high pressure similar to 155 GPa (GigaPascal).

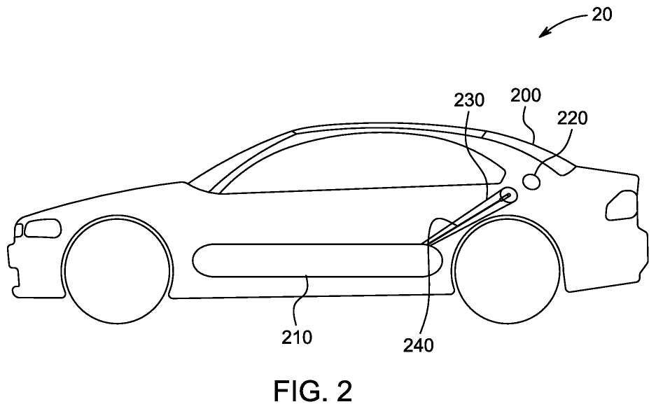

FIG. 2. shows an embodiment of an electric vehicle 200, comprising a rechargeable battery 210, and an electrical conductor 240 via which the rechargeable battery is configured to be charged with electricity.

The electrical conductor 240 is surrounded by or in contact with a coolant in a cylinder 230 surrounding the electrical conductor, cooling the electrical conductor below the characteristic T_{c} (critical temperature) of the electrical conductor material. The electrical conductor is superconducting as a result and has no electrical resistance.

A large electric charge sufficient to charge the rechargeable battery full is configured to pass through the superconducting electrical conductor 240. In some embodiments a software program is used to determine the amount of charge in Coulombs that can be speedily and safely charged to the battery. Preferably this is done in a time that is shorter than it takes to refuel a corresponding internal combustion engine car with diesel or petrol today.

The coolant is typically liquid nitrogen, hydrogen, CF₄ or helium. The electrical conductor is typically made of any of the following: HgTlBaCaCuO, HgBaCaCuO at high pressure similar to 30 GPa, TlBaCaCuO, BiSrCaCuO, YBaCuO, LaSrCuO, LaBaCuO, SrFFeAs, FeSe Im and/or H₂S at high pressure similar to 155 GPa. Some materials have elevated T_{c} critical temperatures at higher pressures, and therefore in some embodiments the pressure surrounding the electrical conductor 240 is increased during charging. In some embodiments the electrical conductor 240 is made of cuprate or Iron-pnictogen.

In some embodiments the electrical conductor 240 is made as an electrical conduit comprised of Hydrogen Sulfide H₂S. The H₂S electrical conductor is highly pressurised, then cooled, to form an electrical conduit with T_{c}=203 K or so at 200 GPa. Some sulphur might optionally also be replaced with phosphorus to elevate T_{c} with higher pressures than 200 GPa possibly to above 273 K. These materials exhibit superconductivity at temperatures at which CF₄ and liquid nitrogen, and possibly other known coolants, stably remain as liquids.

In some embodiments the superconducting electrical conductor 240 is a wire within a cylinder 230, and the cylinder is filled with the liquid coolant, and the cylinder has a cap 220 in the wall of the electric vehicle. By opening the cap, an electrical conductor from an electrical charger is introduced in contact with the electrical conductor 240 and electrical charging provided to the battery 210. Typically, the electrical conductor 240 is connected to both the anode and the cathode of the battery 210, and the electric current from both the anode and the cathode is superconducting.

In some embodiments the electric car battery 210 is charged with an electric charger, which has an electrical conductor, with a cylindrical head with the inner diameter the size of the diameter of the electrical conductor 240, which may be a wire, electrical channel or an electrical conduit. By removing the cap 220 from the electric vehicle 200, the cylindrical head of the electrical conductor of the battery charger is physically connected with the superconducting electrical conductor 240 of the electric vehicle. Thus, the electric charger charges the rechargeable battery 210 of the electric vehicle 200 via the superconducting electrical conductor 240.

Embodiments 20 and 30 can be readily permuted and combined in accordance with the invention. Any materials from FIG. 1 can be used with embodiment 20.

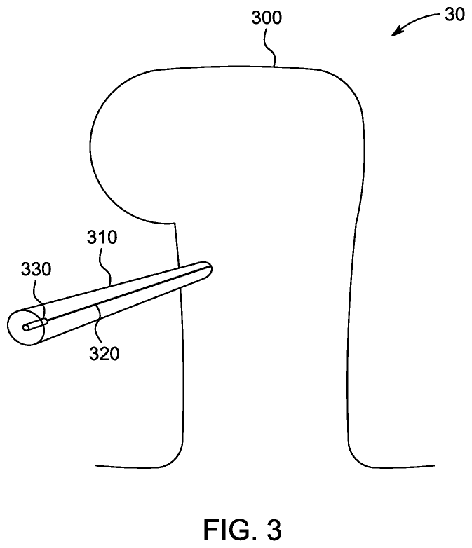

In FIG. 3 an electric vehicle battery charger 300 is configured to charge a rechargeable battery, such as 210 of FIG. 2. The EV battery charger comprises an electrical conductor 320 via which a rechargeable battery is configured to be charged with electricity.

Preferably, the electrical conductor 320 is surrounded or in contact with a coolant, cooling the electrical conductor below the characteristic T_{c} (critical temperature) of the electrical conductor material. This results in the electrical conductor 320 becoming superconducting.

Thus, a large electric charge sufficient to charge the rechargeable battery full can be configured to pass through the superconducting electrical conductor 320 without electrical resistance. This will result in a charging time that is shorter than it takes to refuel a corresponding internal combustion engine car with diesel or petrol.

Typically, the coolant is liquid nitrogen, hydrogen, CF₄ or helium. Typically, the electrical conductor is made of any of the following: HgTlBaCaCuO, HgBaCaCuO at high pressure similar to 30 GPa, TlBaCaCuO, BiSrCaCuO, YBaCuO, LaSrCuO, LaBaCuO, SrFFeAs, FeSe Im and/or H₂S at high pressure similar to 155 GPa. Some of these materials exhibit higher T_{c} critical temperatures, so in some embodiments the pressure surrounding the electrical conductor 320 is increased in some embodiments.

In some embodiments the electrical conductor 320 is made as an electrical conduit comprised of Hydrogen Sulfide H₂S. The H₂S electrical conductor is highly pressurised, then cooled, to form an electrical conduit with T_{c}=203 K or so at 200 GPa. Some sulphur might optionally also be replaced with phosphorus to elevate T_{c} with higher pressures than 200 GPa possibly to above 273 K. These materials exhibit superconductivity at temperatures at which CF₄ and liquid nitrogen, and possibly other known coolants, stably remain as liquids.

High pressure can possibly be realised on the electrical conductor 240, 320 by mechanically pressurising the coolant in some embodiments, for example with a piston. The pressurization and the cooling of the electrical conductor can be configured to begin only before charging is about to take place. It is sufficient that these highly pressurized cooled conditions exist only during the charging. The momentary pressurization and cooling for charging periods saves energy, as high pressures or cool temperatures do not need to be maintained in the conductors of the electric vehicle or the charger when the battery is not being recharged.

The superconducting electrical conductor 320 is configured as a wire or a conduit channel within a cylinder 310, and the cylinder is filled with the liquid coolant, and the cylinder has a cap 330.

Typically, an electric vehicle has an electrical conductor 240, with an inner diameter of a wire or an electrical channel or conduit. By removing the cap 330 from the cylindrical head of the electrical conductor 310 with the charger 300, the superconducting electrical conductor of the electric vehicle battery charger is physically connected with a superconducting electrical conductor of the electric vehicle. The electric charger 300 then charges the rechargeable battery 210 of the electric vehicle 200 via the superconducting electrical conductors 240, 320. Typically, the electrical conductor 320 is connected to both the anode and the cathode of the battery 210, and the electric current from both the anode and the cathode is superconducting.

Embodiments 30 and 20 can be readily permuted and combined in accordance with the invention. Any materials from FIG. 1 can be used with embodiment 30.

Typically, a software program product is used to measure the charging level of the battery 210 and determine the correct additional charge needed. The software program may also instruct the charger 300 to deposit this correct amount of electric charge to the battery 210 in accordance with the invention.

The invention has been explained above with reference to the aforementioned embodiments and several commercial and industrial advantages have been demonstrated. The methods and arrangements of the invention allow to deposit a correct amount of electric charge to an electric vehicle battery in a matter of seconds. The worst inconvenience in using an electric vehicle to the consumer, i.e. charging the battery for a frustratingly long time, is thus removed by the invention. Also, the need for battery swap schemes is removed, as the inventive charging takes the same or less time than a battery swap and is more convenient as the battery remains the same.

The invention has been explained above with reference to the aforementioned embodiments. However, it is clear that the invention is not only restricted to these embodiments, but comprises all possible embodiments within the spirit and scope of the inventive thought and the following patent claims.

### REFERENCES

https://en.wikipedia.org/wiki/Superconductivity#Applications

1. An electric vehicle, comprising a rechargeable battery, and an electrical conductor via which the rechargeable battery is configured to be charged with electricity, characterized in that,
the electrical conductor is surrounded or in contact with a coolant, cooling the electrical conductor below the characteristic T_{c} (critical temperature) of the electrical conductor material,
the electrical conductor is superconducting.

2. An electric vehicle as claimed in claim 1, characterized in that, a large electric charge sufficient to charge the rechargeable battery full is configured to pass through the superconducting electrical conductor in a time that is shorter than it takes to refuel a corresponding internal combustion engine car with diesel or petrol.

3. An electric vehicle as claimed in claim 1, characterized in that, the coolant is liquid nitrogen, hydrogen, CF₄ or helium.

4. An electric vehicle as claimed in claim 1, characterized in that, the electrical conductor is any of the following: HgTlBaCaCuO, HgBaCaCuO at high pressure similar to 30 GPa, TlBaCaCuO, BiSrCaCuO, YBaCuO, LaSrCuO, LaBaCuO, SrFFeAs, FeSe Im and/or H₂S at high pressure similar to 155 GPa.

5. An electric vehicle as claimed in claim 1, characterized in that, the superconducting electrical conductor is a wire within a cylinder, and the cylinder is filled with the liquid coolant, and the cylinder has a cap in the wall of the electric vehicle.

6. An electric vehicle as claimed in claim 5, characterized in that,
an electric charger has an electrical conductor, with a cylindrical head with the inner diameter of the wire,
by removing the cap from the electric vehicle, the cylindrical head of the electrical conductor of the battery charger is physically connected with the superconducting electrical conductor of the electric vehicle,
the electric charger charges the rechargeable battery of the electric vehicle via the superconducting electrical conductor.

7. An electric vehicle as claimed in claim 1, characterized in that, the electrical conductor is a conduit made of H₂S at high pressure 200 GPa, which conduit is then cooled.

8. An electric vehicle as claimed in claim 1, characterized in that, the electrical conductor is a conduit made of H₂S and H₂Ph, or H₂Ph only at high pressure of 200 GPa or over, which conduit is cooled.

9. An electric vehicle battery charger, configured to charge a rechargeable battery, comprising an electrical conductor via which a rechargeable battery is configured to be charged with electricity, characterized in that,
the electrical conductor is surrounded or in contact with a coolant, cooling the electrical conductor below the characteristic T_{c} (critical temperature) of the electrical conductor material,
the electrical conductor is superconducting.

10. An electric vehicle battery charger as claimed in claim 9, characterized in that, a large electric charge sufficient to charge the rechargeable battery full is configured to pass through the superconducting electrical conductor in a time that is shorter than it takes to refuel a corresponding internal combustion engine car with diesel or petrol.

11. An electric vehicle battery charger as claimed in claim 9, characterized in that, the coolant is liquid nitrogen, hydrogen, CF₄ or helium.

12. An electric vehicle battery charger as claimed in claim 9, characterized in that, the electrical conductor is any of the following: HgTlBaCaCuO, HgBaCaCuO at high pressure similar to 30 GPa, TlBaCaCuO, BiSrCaCuO, YBaCuO, LaSrCuO, LaBaCuO, SrFFeAs, FeSe Im and/or H₂S at high pressure similar to 155 GPa.

13. An electric vehicle battery charger as claimed in claim 9, characterized in that, the superconducting electrical conductor is a wire within a cylinder, and the cylinder is filled with the liquid coolant, and the cylinder has a cap.

14. An electric vehicle battery charger as claimed in claim 13, characterized in that,
an electric vehicle has an electrical conductor, with a cylindrical head with the inner diameter of the wire,
by removing the cap from the cylindrical head of the electrical conductor with the charger, the superconducting electrical conductor of the electric vehicle battery charger is physically connected with a superconducting electrical conductor of the electric vehicle,
the electric charger charges the rechargeable battery of the electric vehicle via the superconducting electrical conductors.

15. An electric vehicle charger as claimed in claim 9, characterized in that, the electrical conductor is a conduit made of H₂S at high pressure 200 GPa, which conduit is then cooled.

16. An electric vehicle charger as claimed in claim 9, characterized in that, the electrical conductor is a conduit made of H₂S and H₂Ph, or H₂Ph only at high pressure of 200 GPa or over, which conduit is cooled after pressurization.

17. An electric vehicle charging software program product, stored in a non-transitory memory medium, configure to operate a system comprising a rechargeable battery, and an electrical conductor via which the rechargeable battery is configured to be charged with electricity, characterized in that,
the electrical conductor is surrounded or in contact with a coolant, cooling the electrical conductor below the characteristic T_{c} (critical temperature) of the electrical conductor material,
the electrical conductor is superconducting,
the software is configured to measure either with sensors or with use data the amount of electric charge lacking from the electric vehicle battery, and
the software is configured to instruct an electric charger to deposit a determined electric charge through the superconducting electric conductor.
